(19) United States
(12) Patent Application Publication
(10) Pub. No.: US 2002/0157244 A1
(43) Pub. Date: Oct. 31, 2002

(54) Apparatus and method for installing and extracting components on a printed circuit board

(76) Inventors: Vernon Bollesen, Milpitas, CA (US); Peter Cuong Dac Ta, Hayward, CA (US)

Correspondence Address: SUN MICROSYSTEMS, INC, 901 San Antonio Road MS UPAL01-521, Palo Alto, CA, 94303, US

(21) Appl. No.: 09/845,436

(22) Filed: Apr. 30, 2001

(51) Int. Cl. B23P 19/00; H05K 3/00; H05K 3/30

(52) U.S. Cl. 29/829; 29/832; 29/764

(57) ABSTRACT

An apparatus for installing and extracting a component on a printed circuit board includes an adjustable body having a first angled edge and a second angled edge. Each of the first and second angled edges is formed with a flange engageable with a surface of the component. The adjustable body may be adjustable to a first position to allow each of the flanges to engage a surface of the component. The adjustable body may include a first tab and a second tab extending therefrom. The first and second tabs are moved toward each other to adjust the adjustable body within a range of positions.

### RELATED APPLICATION

This application is related to application Ser. No. ______, pending, entitled “Component Installer and Extractor” which is assigned to the assignee of the present application and filed concurrently herewith.

### BACKGROUND OF THE INVENTION

1. Field of the Invention

The present invention relates generally to components on a printed circuit board, and more specifically to installing and extracting such components.

2. Background Information

As computer systems become increasingly sophisticated, their internal components often become smaller and more densely situated. For example, a printed circuit board (PCB), such as a motherboard, for a computer system may have numerous integrated circuits disposed on the surface of the PCB. Adjacent integrated circuits are placed close to one another to take advantage of the entire surface area of the PCB. Although integrated circuits are often installed on a PCB by machines, some components may be installed by a user. However, because of the dense grouping of integrated circuits and other components on a PCB, it is difficult to manually install a component that is to be located adjacent another component. Furthermore, it may be necessary to remove the component if it is damaged or needs to be upgraded, and removing the component can be as problematic as installing the component because of the space constraints. Manually installing and extracting a component can also subject the component to undesirable forces.

### SUMMARY OF THE INVENTION

An apparatus for moving a component of a computer system comprises an adjustable body having a first angled edge and a second angled edge. Each of the first and second angled edges is formed with a flange engageable with a surface of the component. In one embodiment, a first tab and a second tab extend from the adjustable body. When the first and second tabs are moved toward each other, the first and second angled edges are moved relative to each other.

Additional features and benefits of the present invention will become apparent from the detailed description, figures and claims set forth below.

### BRIEF DESCRIPTION OF THE DRAWINGS

Various embodiments of the present invention will be described in detail with reference to the following drawings. The present invention is illustrated by way of example and not limitation in the accompanying figures.

FIG. 1 illustrates a perspective view of one embodiment of an adjustable claw engaged with a component in accordance with the teachings of the present invention.

FIG. 2A illustrates a side view of another embodiment of an adjustable claw adjacent a component in accordance with the teachings of the present invention.

FIG. 2B illustrates a side view of the adjustable claw shown in FIG. 2A engaged with a component that is disposed on a printed circuit board in accordance with the teachings of the present invention.

FIG. 3A illustrates a perspective view of another embodiment of an adjustable claw engaged with a component in accordance with the teachings of the present invention.

FIG. 3B illustrates an exploded view of the adjustable claw shown in FIG. 3.

FIG. 4 illustrates a perspective view of one part of an adjustable claw in accordance with the teachings of the present invention.

FIG. 5 illustrates a perspective view of yet another embodiment of an adjustable claw engaged with a component in accordance with the teachings of the present invention.

### DETAILED DESCRIPTION

The description and accompanying drawings are for purposes of illustration and are not to be used to construe the invention in a restrictive manner. In the following description, specific details are set forth in order to provide a thorough understanding of the invention. However, it will be apparent to one of ordinary skill in the art that the invention can be practiced without these specific details. In particular, the invention will be described with specific reference to memory modules, but it is appreciated that the invention is not limited to use with any one component.

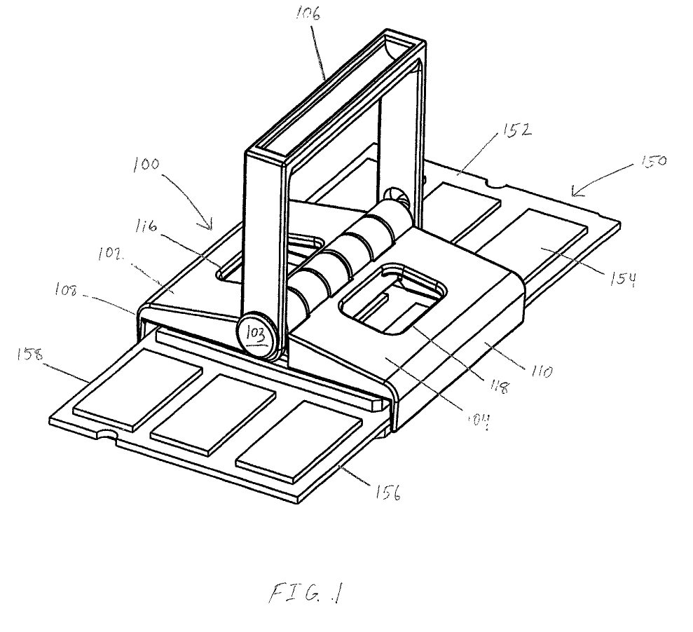

FIG. 1 illustrates an adjustable claw 100 engaged with a component 150, such as a memory module or other component which may be used in a computer system. Claw 100 includes an adjustable body formed with a first claw member 102 and a second claw member 104. In one embodiment, members 102 and 104 are identical pieces. Thus, manufacturing and repair of claw 100 may be facilitated. Claw 100 also includes an adjustable handle 106. Members 102 and 104 and handle 106 are independently rotateable about a common axis which is the longitudinal axis of a pin 103. Members 102 and 104 and handle 106 are held together by pin 103. Members 102 and 104, handle 106 and pin 103 may be made from plastic or any suitably rigid material.

Member 102 has an angled edge 108 which is positioned adjacent edge 158 of component 150 such that a flange (not shown) extending from angled edge 108 is engageable with the bottom surface or underside of component 150. Member 102 may be formed with an opening 116 to allow a subcomponent 154 of component 150 to be seen underneath member 102. Member 104 has an angled edge 110 which is positioned adjacent edge 156 of component 150 such that a flange (not shown) extending from angled edge 110 is engageable with the underside of component 150. Member 104 may be formed with an opening 118 to allow a subcomponent 154 of component 150 to be seen underneath member 104. The flanges of angled edges 108 and 110 engage the underside of component 150 together such that adjustable claw 100 “grabs” component 150. Subsequently, adjustable claw 100 may be used to move component 150 by, for example, lifting component 150 using handle 106.

It should be noted that adjustable claw 100 may be turned around such that angled edge 108 is adjacent edge 156 and angled edge 110 is adjacent edge 158. Furthermore, openings 116 and 118 in members 102 and 104, respectively, may be used as finger holds to allow a user to push members 102 and 104 toward each other such that adjustable claw 100 maintains a secure hold on component 150.

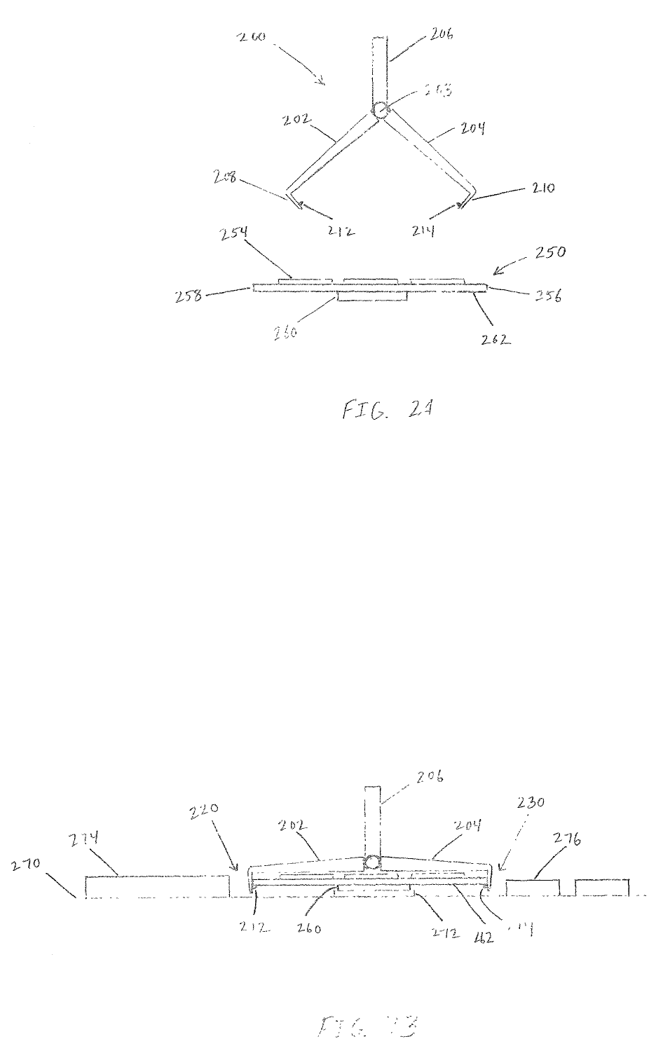

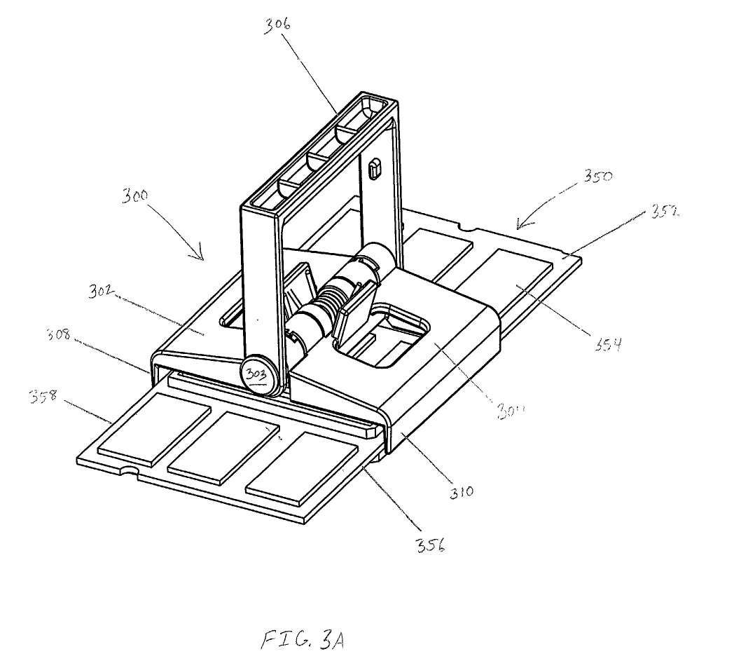

FIG. 2A illustrates a side view of an adjustable claw 200 in a partially closed position. Claw 200 includes an adjustable body formed with a first claw member 202 and a second claw member 204. In one embodiment, members 202 and 204 are identical pieces. In another embodiment, the undersides of members 202 and 204 are formed with a recessed or hollow area to accommodate subcomponents 254 when claw 200 is engaged with component 250. Claw 200 also includes an adjustable handle 206. Members 202 and 204 and handle 206 are independently rotateable about a common axis which is the longitudinal axis of a pin 203. Members 202 and 204 and handle 206 are held together by pin 203. Members 202 and 204, handle 206 and pin 203 may be made from plastic or any suitably rigid material.

Member 202 has an angled edge 208 from which a flange 212 extends. Member 204 has an angled edge 210 from which a flange 214 extends. In one embodiment, flanges 212 and 214 are centered along the widths of angled edges 208 and 210, respectively. Additionally, flanges 212 and 214 may extend orthogonally from angled edges 208 and 210, respectively, to better engage the underside 262 of component 250 when claw 200 is adjusted to grab component 250.

When claw 200 is adjusted to an open position to grab component 250, the angle between members 202 and 204 is wide enough to allow flanges 212 and 214 to clear edges 258 and 256, respectively, of component 250. Because different components may have different dimensions, an open position of claw 200 for grabbing a component is not defined by any one angle between members 202 and 204. Furthermore, claw 200 may be formed with larger or smaller members 202 and 204 to provide a better fit for larger or smaller components.

FIG. 2B illustrates a side view of claw 200 in a securing position around component 250. Claw 200 may be viewed in FIG. 2B as completing installation of component 250 on printed circuit board 270 or beginning extraction of component 250. In either situation, the space between components 274 and 276 on printed circuit board 270 is just large enough to accommodate component 250 coupled to socket 272 via connector 260. Gaps 220 and 230 between the edges of component 250 and components 274 and 276 may not be large enough for a user to grab component 250 with his or her fingers and install/extract component 250 without damaging neighboring components 274 and 276. Grabbing component 250 by its edges length-wise (into and out of page) is not a suitable alternative because doing so could subject component 250 to undesirable bending stresses.

Because angled edges 208 and 210 of claw 200 have a thin profile, they can be positioned within gaps 220 and 230 to engage the underside 262 of component 250 with flanges 212 and 214. When claw 200 is engaged with component 250, there is clearance between claw 200 and components 274 and 276 to move claw 200 laterally during installation/extraction of component 250. Thus, claw 200 may be used to provide safer installation/extraction of component 250.

To install component 250 on printed circuit board 270 using claw 200, component 250 is engaged by claw 200 and then positioned over printed circuit board 270 such that connector 260 is positioned over socket 272. Once component 250 is properly positioned, claw 200 is pushed down until connector 260 mates securely with socket 272. Claw 200 is then disengaged from component 250. To extract component 250 from printed circuit board 270 using claw 200, component 250 is engaged by claw 200 and then pulled out of socket 272 by pulling on handle 206.

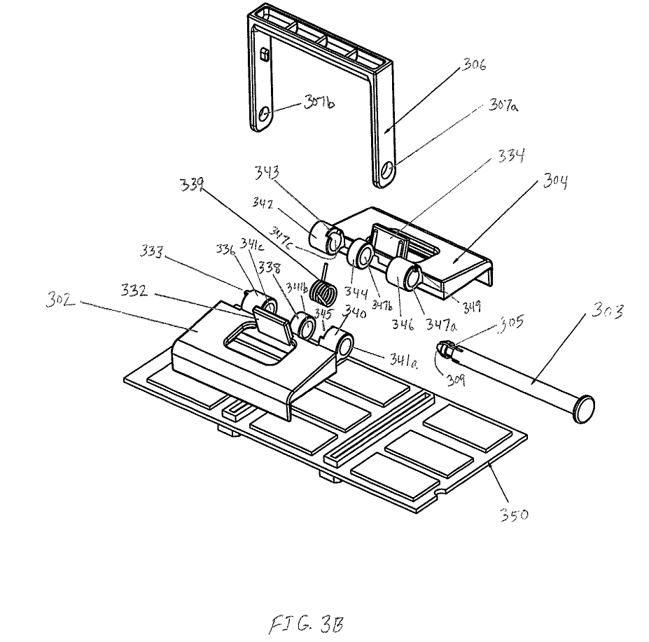

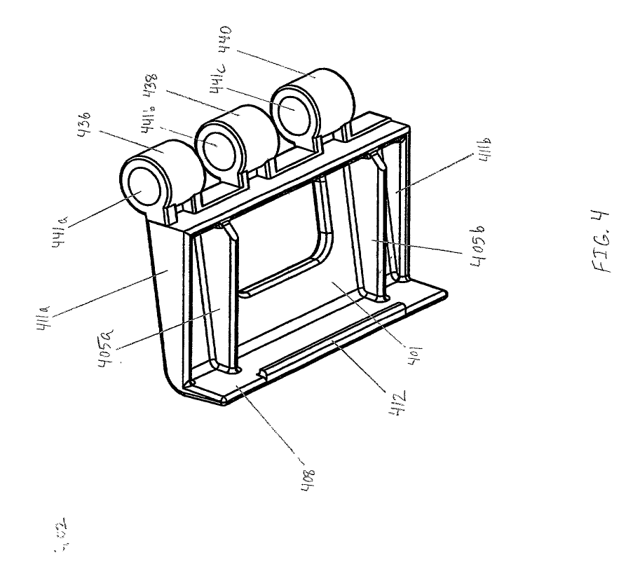

FIGS. 3A and 3B illustrate a perspective view and an exploded view, respectively, of another embodiment of an adjustable claw according to the present invention. Adjustable claw 300 includes an adjustable body formed with a first claw member 302 and a second claw member 304. In one embodiment, members 302 and 304 are identical pieces. The undersides of members 302 and 304 are formed with a recessed or hollow area to accommodate subcomponents 354 on a top surface 352 of component 350 when claw 300 is engaged with component 350.

Claw 300 also includes an adjustable handle 306. Members 302 and 304 and handle 306 are independently rotateable about a common axis which is the longitudinal axis of a pin 303. Members 302 and 304, handle 306 and spring 339 are held together by pin 303 which is inserted through through-holes 341a, 341b and 341c of member 302, through-holes 347a, 347b and 347c of member 304, through-holes 307a and 307b of handle 306, and spring 339. Groove 305 of pin 303 prevents pin 303 from slipping out of hole 307b once end 309 of pin 303 is pushed through hole 307b. End 309 is tapered to facilitate pushing end 309 through through-holes 307a and 307b, which are slightly smaller than the widest part of the tapered area of end 309. Members 302 and 304, handle 306 and pin 303 may be made from plastic or any suitably rigid material.

Member 302 has an angled edge 308 from which a flange (not shown) extends. Member 304 has an angled edge 310 from which a flange (not shown) extends. The flanges of angled edges 308 and 310 engage the underside of component 350 in a manner similar to that shown in FIG. 2B with respect to flanges 212 and 214. When claw 300 engages component 350, angled edge 308 abuts edge 358 of component 350 and angled edge 310 abuts edge 356 of component 350. It is appreciated that claw 300 may be used in an alternative orientation such that angled edge 308 abuts edge 356 and angled edge 310 abuts edge 358.

Members 302 and 304 engage each other to permit the insertion of pin 303 while limiting their range of rotation around pin 303. Specifically, member 302 is formed with eyelets 336, 338 and 340 which are lined up with eyelets 342, 344 and 346 of member 304 in an alternating manner. Thus, eyelet 336 is located between eyelets 342 and 344, eyelet 338 is located between eyelets 344 and 346, and eyelet 340 is located adjacent eyelet 346. Spring 339 is located between eyelets 344 and 338. Eyelet 336 has a protrusion 333 which engages groove 343 of eyelet 342. Eyelet 346 has a protrusion 349 which engages groove 345 of eyelet 340. Grooves 343 and 345 define the range of movement of protrusions 333 and 349, respectively. Accordingly, members 302 and 304 have a limited range of rotation around pin 303.

Members 302 and 304 are formed with tabs 332 and 334, respectively, which allow a user to open claw 300 by concurrently pushing tabs 332 and 334 toward each other. Opening claw 300 disengages claw 300 from component 350. By concurrently pushing tabs 332 and 334 toward each other, claw 300 may be symmetrically adjustable. Spring 339 resists the movement of tabs 332 and 334 toward each other. Opposite ends of spring 339 press against tabs 332 and 334 to push tabs 332 and 334 away from each other. Thus, spring 339 forces claw 300 to a securing position (as limited by grooves 343 and 345) which securely engages component 350.

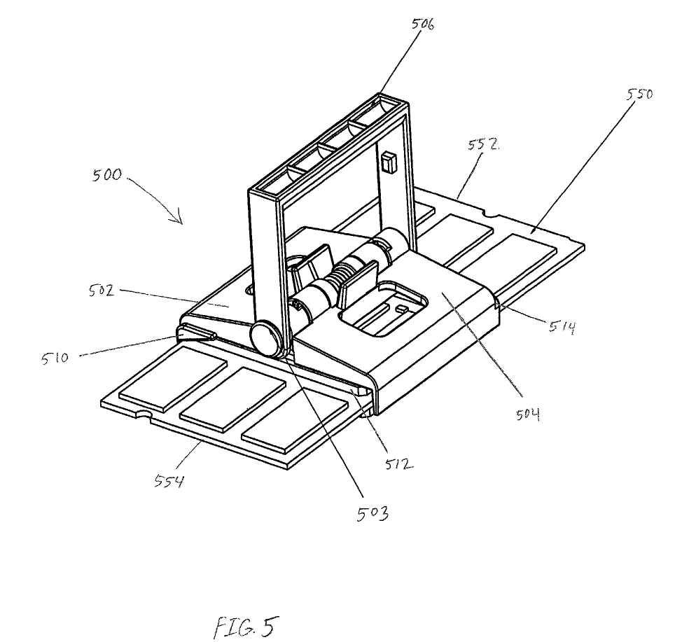

FIG. 4 illustrates a perspective view of one embodiment of a claw member. Claw member 402 is integrally formed with eyelets 436, 438 and 440 which have through-holes 441a, 441b and 441c, respectively. Through-holes 441a, 441b and 441c are aligned with one another. Eyelet 436 may be formed with a groove, such as groove 345 shown in FIG. 3B, and eyelet 440 may be formed with a protrusion, such as protrusion 333 shown in FIG. 3B. A flange 412 extends from an angled edge 408 of claw member 402. In one embodiment, flange 412 is integrally formed with angled edge 408. It is appreciated that flange 412 may be longer or shorter as necessary to securely engage the underside of a component.

Partitions 405a and 405b extend from an inner surface 401 of claw member 402. The area bounded by partitions 405a and 405b and inner surface 401 provides room to accommodate a subcomponent or other feature which extends from the surface of the component being engaged. Panels 411a and 411b may be sized such that the bottom edges of panels 411a and 411b press down on a component when the component is being installed. It is appreciated that an adjustable claw comprising claw member 402 may be positioned to engage a component such that the bottom edges of panels 411a and 411b do not press down on fragile subcomponents of the component during installation. Furthermore, partitions 405a and 405b may be used, in addition to or alternatively to panels 411a and 411b, to press down on the component during installation.

FIG. 5 illustrates a perspective view of yet another embodiment of an adjustable claw according to the present invention. Adjustable claw 500 is similar to adjustable claw 300 shown in FIGS. 3A and 3B. Adjustable claw 500 includes an adjustable body formed with a first claw member 502 and a second claw member 504. In one embodiment, members 502 and 504 are identical pieces. Claw 500 also includes an adjustable handle 506. Members 502 and 504 and handle 506 are independently rotateable about a common axis which is the longitudinal axis of a pin 503. Members 502 and 504 and handle 506 are held together by pin 503. Member 502 is formed with a flange 510. Member 504 is similarly formed with a flange 514. Flanges 510 and 514 help prevent claw 500 from inadvertently shifting its position along component 550 once claw 500 is engaged with component 550. For example, if claw 500 shifts toward end 552 of component 550, flange 510 contacts subcomponent 512 and prevents any further movement of claw 500 toward end 552. Flange 514 operates similarly if claw 500 shifts away from end 552.

In the foregoing detailed description, the present invention has been described with reference to specific exemplary embodiments. However, it will be evident that various modifications and changes may be made without departing from the broader scope and spirit of the present invention. For example, an adjustable claw according to the present invention may have a flexible one-piece body rather than a two-piece body which is rotateable about a pin. The present specification and figures are accordingly to be regarded as illustrative rather than restrictive.

What is claimed is:

1. An apparatus for moving a component of a computer system, the apparatus comprising:
an adjustable body;
a first angled edge of said adjustable body; and
a second angled edge of said adjustable body;
wherein each of said first and second angled edges is formed with a flange engageable with a surface of the component.

2. The apparatus of claim 1, wherein said adjustable body is adjustable to a first position to allow each of said flanges to engage said surface of the component.

3. The apparatus of claim 1, further comprising:
a first tab extending from said adjustable body; and
a second tab extending from said adjustable body;
wherein said first and second angled edges are moved relative to each other when said first and second tabs are moved toward each other.

4. The apparatus of claim 3 wherein a distance between said first and second angled edges increases when said first and second tabs are moved toward each other.

5. The apparatus of claim 1, further comprising a handle coupled to said adjustable body.

6. The apparatus of claim 5, wherein said handle is adjustable independently from said adjustable body.

7. The apparatus of claim 1, further comprising first and second finger holds of said adjustable body.

8. The apparatus of claim 1, wherein said adjustable body is symmetrically adjustable.

9. The apparatus of claim 1, wherein said adjustable body is configured to accommodate a subcomponent on the component when said adjustable body is engaged with the component.

10. An extraction apparatus for a memory module, the apparatus comprising:
a claw having a first member and a second member, wherein said first and second members are rotateable about a common axis; and
a handle rotateable about said common axis;
wherein said claw is engageable with the memory module when said claw is in an open position.

11. The apparatus of claim 10, wherein said first and second members are identical.

12. The apparatus of claim 10, wherein said common axis is a longitudinal axis of a pin, wherein said first member, said second member and said handle are rotateably coupled to said pin.

13. The apparatus of claim 12, further comprising:
a first tab extending from said first member; and
a second tab extending from said second member.

14. The apparatus of claim 13, wherein said claw is disengageable from said memory module when said first and second tabs are moved toward each other.

15. The apparatus of claim 13, further comprising a spring abutting said first and second tabs, wherein said spring biases said first and second tabs away from each other.

16. The apparatus of claim 10, wherein said first member comprises a protrusion and said second member comprises a groove, said protrusion engaging said groove to limit the rotation of said first and second members.

17. The apparatus of claim 10, wherein said first and second members are integrally formed with flanges to engage a bottom surface of the memory module.

18. An apparatus comprising:
first engaging means for engaging a bottom surface of a substrate;
second engaging means for engaging said bottom surface of said substrate;
connecting means for rotateably connecting said first and second engaging means relative to each other; and
lifting means for lifting the apparatus when said first and second engaging means are engaged with said bottom surface of said substrate.

19. The apparatus of claim 18, further comprising biasing means for biasing said first and second engaging means toward said substrate.

20. The apparatus of claim 19, further comprising disengaging means for disengaging said first and second engaging means from said bottom surface of said substrate.

21. The apparatus of claim 20, further comprising means for limiting the rotation of said first and second engaging means relative to each other.

22. A method of extracting a component from a printed circuit board, the method comprising:
engaging the component with an adjustable claw such that a bottom surface of the component is supported by said adjustable claw; and
pulling said adjustable claw away from the printed circuit board while said adjustable claw is engaged with the component.

23. The method of claim 22, wherein said engaging comprises:
opening said adjustable claw to a first position;
placing said adjustable claw over the component; and
closing said adjustable claw to a second position.

24. A method of installing a component in a socket on a printed circuit board, the method comprising:
engaging the component with an adjustable claw;
positioning the component over the socket using said adjustable claw; and
pushing said adjustable claw toward the socket such that the component engages the socket.

25. The method of claim 24, wherein said engaging comprises:
opening said adjustable claw to a first position;
placing said adjustable claw over the component; and
closing said adjustable claw to a second position.
